(19) United States
(12) Patent Application Publication
(10) Pub. No.: US 2012/0280281 A1
(43) Pub. Date: Nov. 8, 2012

(54) GALLIUM NITRIDE OR OTHER GROUP III/V-BASED SCHOTTKY DIODES WITH IMPROVED OPERATING CHARACTERISTICS

(75) Inventor: Sandeep R. Bahl, Palo Alto, CA (US)

(73) Assignee: NATIONAL SEMICONDUCTOR CORPORATION, Santa Clara, CA (US)

(21) Appl. No.: 13/101,378

(22) Filed: May 5, 2011

(51) Int. Cl. H01L 29/872; H01L 21/20

(52) U.S. Cl. 257/201; 438/478; 257/E29.338; 257/E21.09

(57) ABSTRACT

A semiconductor device includes a first Group III/V layer and a second Group III/V layer over the first Group III/V layer. The first and second Group III/V layers are configured to form an electron gas layer. The semiconductor device also includes a Schottky electrical contact having first and second portions. The first portion is in sidewall contact with the electron gas layer. The second portion is over the second Group III/V layer and is in electrical connection with the first portion of the Schottky electrical contact. The first portion of the Schottky electrical contact and the first or second Group III/V layer can form a Schottky barrier, and the second portion of the Schottky electrical contact can reduce an electron concentration near the Schottky barrier under reverse bias.

### TECHNICAL FIELD

This disclosure is generally directed to discrete semiconductor devices and integrated circuits. More specifically, this disclosure is directed to gallium nitride (GaN) or other Group III/V-based Schottky diodes with improved operating characteristics.

### BACKGROUND

Group III/V semiconductor devices are commonly used in high-speed, low-noise, and power applications. A Group III/V device refers to a semiconductor device formed using a compound having at least one Group III element and at least one Group V element. One “family” of Group III/V compounds includes gallium nitride (GaN) and other Group III nitrides, referring to compounds having at least one Group III element and nitrogen.

A Schottky diode formed using Group III/V compounds includes a Schottky barrier, which is formed at a metal-semiconductor junction. The height of the Schottky barrier affects various operating characteristics of the Schottky diode. For example, lower barrier heights are often associated with lower turn-on voltages but higher leakage currents and lower breakdown voltages. Higher barrier heights are often associated with lower leakage currents and higher breakdown voltages but higher turn-on voltages, which lead to power losses and lower efficiencies.

Moreover, it is often not possible to integrate the fabrication of Group III/V-based Schottky diodes and Group III/V transistors. This means it is usually not possible to form a single integrated circuit with both types of components. This typically increases the size and fabrication costs of devices that require both Group III/V-based Schottky diodes and transistors.

### BRIEF DESCRIPTION OF THE DRAWINGS

For a more complete understanding of this disclosure and its features, reference is now made to the following description, taken in conjunction with the accompanying drawings, in which:

FIG. 1 illustrates an example Group III/V-based Schottky diode with improved operating characteristics according to this disclosure;

FIGS. 2A through 2C illustrate example band diagrams associated with the Group III/V-based Schottky diode of FIG. 1 according to this disclosure;

FIGS. 3A through 3F illustrate an example technique for forming the Group III/V-based Schottky diode of FIG. 1 according to this disclosure;

FIGS. 4 and 5 illustrate other example Group III/V-based Schottky diodes with improved operating characteristics according to this disclosure; and

FIG. 6 illustrates an example method for forming a Group III/V-based Schottky diode with improved operating characteristics according to this disclosure.

### DETAILED DESCRIPTION

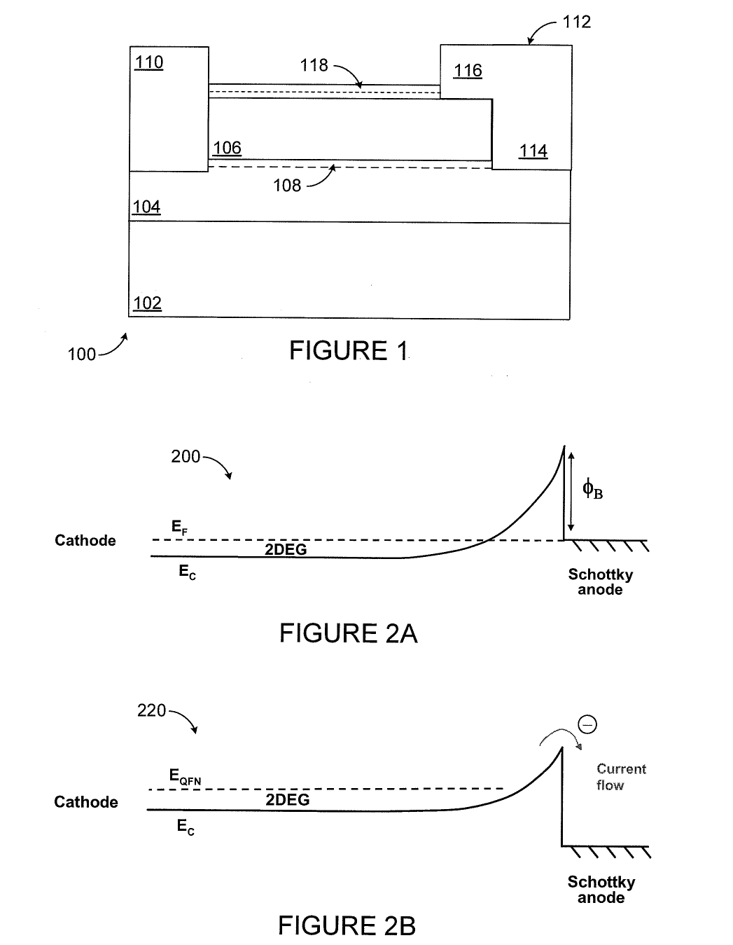

FIGS. 1 through 6, discussed below, and the various embodiments used to describe the principles of the present invention in this patent document are by way of illustration only and should not be construed in any way to limit the scope of the invention. Those skilled in the art will understand that the principles of the invention may be implemented in any type of suitably arranged device or system.

FIG. 1 illustrates an example Group III/V-based Schottky diode 100 with improved operating characteristics according to this disclosure. As shown in FIG. 1, the Schottky diode 100 includes a semiconductor substrate 102, which represents any suitable substrate on which other layers or structures are formed. For example, the substrate 102 could represent a silicon <111> substrate or a silicon on insulator (SOI) substrate with silicon <111> as a top layer and silicon <100> as a handle substrate. The substrate 102 could also represent a sapphire, silicon carbide, gallium nitride, gallium arsenide, indium phosphide, or other semiconductor substrate. The substrate 102 could have any suitable size, such as a three-inch, four-inch, six-inch, eight-inch, twelve-inch, or other diameter.

The Schottky diode 100 also includes at least one Group III/V lower layer 104 and at least one Group III/V upper layer 106. The layers 104-106 denote layers of material that create a two-dimensional electron gas (2DEG) layer 108 at the interface of the layers 104-106.

Each of the layers 104-106 could be formed from any suitable Group III/V material(s). For instance, each of the layers 104-106 could be formed from one or more Group III nitride materials. Example Group III elements include indium, gallium, and aluminum. Example Group V elements include nitrogen, arsenic, and phosphorus. Example Group III nitrides include gallium nitride (GaN), aluminum gallium nitride (AlGaN), indium aluminum nitride (InAlN), indium aluminum gallium nitride (InAlGaN), aluminum nitride (AlN), indium nitride (InN), and indium gallium nitride (InGaN). Other example Group III/V materials include Group III arsenide and Group III phosphide materials, such as gallium arsenide (GaAs), aluminum gallium arsenide (AlGaAs), indium phosphide (InP), and indium gallium phosphide (InGaP). In some embodiments, the lower layer 104 includes a nucleation layer, a buffer layer, and a channel layer, while the upper layer 106 includes a barrier layer. In particular embodiments, the lower layer 104 includes an aluminum nitride nucleation layer, an aluminum gallium nitride buffer layer, and a gallium nitride channel layer, and the upper layer 106 includes an aluminum gallium nitride barrier layer.

Each of the layers 104-106 could also be formed in any suitable manner. For example, the layers 104-106 could represent Group III/V epitaxial layers grown using a Metal-Organic Chemical Vapor Deposition (MOCVD) or Molecular Beam Epitaxy (MBE) technique. Moreover, each layer 104-106 could represent a single layer of material or multiple layers of the same or different material. In addition, each of the layers 104-106 could have any suitable thickness.

The electron gas layer 108 forms along the interface of the lower and upper layers 104-106. A two-dimensional electron gas layer typically represents a sheet of electrons where electrons are confined and can move freely within two dimensions but are limited in movement in a third dimension. In a Group III nitride device, for example, the electron gas layer 108 forms as a result of a difference in polarization charges in the lower and upper layers 104-106. The difference in polarization charges could be due to the difference in composition and strain between the lower and upper layers 104-106.

The electron gas layer 108 here extends between two electrical contacts 110-112 and forms an electrical channel. The electrical contacts 110-112 represent contacts for electrically coupling the Schottky diode 100 to external signal lines or other components. In FIG. 1, the electrical contact 110 could represent the cathode of the Schottky diode 100, and the electrical contact 112 could represent the anode of the Schottky diode.

The electrical contact 110 could represent an Ohmic contact. An Ohmic contact represents an electrical contact having a substantially linear and substantially symmetric voltage-current curve. The electrical contact 110 could be formed using an alloy that includes titanium, aluminum, nickel, gold, or tungsten. Any suitable technique could be used to form the electrical contact 110, such as by alloying multiple conductive materials. In this example, the electrical contact 110 is shown as being formed completely through the upper layer 106 into the lower layer 104. However, other approaches could also be used, such as by forming the electrical contact 110 on the upper layer 106 or in a recess partially (but not completely) through the upper layer 106.

The electrical contact 112 represents a Schottky contact associated with a Schottky barrier. A Schottky barrier is formed at a metal-semiconductor junction, which in this case is located at the junction of the lower/upper layers 104-106 and the electrical contact 112. The Schottky barrier causes the electrical contact 112 to form a blocking or Schottky contact, meaning it has a non-linear and asymmetric voltage-current curve. The electrical contact 112 can be formed by etching the upper layer 106 prior to deposition of metal or other conductive material forming the electrical contact 112. The electrical contact 112 could be formed from any suitable material(s), such as titanium, aluminum, nickel, gold, or tungsten. Any suitable technique could be used to form the electrical contact 110, such as by depositing and etching conductive material(s).

The electrical contact 112 here includes multiple portions 114-116. The portion 114 of the electrical contact 112 is in sidewall contact with the electron gas layer 108, while the portion 116 of the electrical contact 112 extends over the upper layer 106. The portion 116 may be said to form a resurf electrode, and the portion 116 is in electrical contact with the portion 114. The electrical contact 112 therefore effectively wraps around part of the upper layer 106.

The electrical contact 112 can have a lower Schottky barrier height to the electron gas layer 108 than to the upper layer 106. For instance, the electrical contact 112 could have a Schottky barrier height of 0.8 eV to the electron gas layer 108 and 1.5 eV to the upper layer 106.

The electrical contact 112 has a lower Schottky barrier height compared to electrical contacts in conventional Group III/V Schottky diodes. As described above, a lower Schottky barrier height would ordinarily lead to higher leakage currents and lower breakdown voltages but achieve lower turn-on voltages. This is why conventional Schottky diodes often require a tradeoff between leakage current/breakdown voltage and turn-on voltage. However, the presence of the portion 116 of the electrical contact 112 over the upper layer 106 helps to deplete the electron gas layer 108 at high reverse bias voltages. This reduces electron concentration near the Schottky barrier as the reverse bias increases, providing improved voltage handling capability. It therefore helps to prevent a large electric field from reaching the Schottky barrier. This allows the formation of a Group III/V-based Schottky diode with a lower barrier height that achieves lower leakage current, higher breakdown voltage, and lower turn-on voltage.

At least one dielectric layer 118 can be formed over the upper layer 106. The dielectric layer 118 could be formed from any suitable material(s), such as silicon nitride, aluminum oxide, or silicon dioxide. Also, the dielectric layer 118 can be formed in any suitable manner. In addition, the dielectric layer 118 could include any number and type(s) of layers. In particular embodiments, the dielectric layer 118 includes a gate oxide layer and/or a passivation layer.

Although FIG. 1 illustrates one example of a Group III/V-based Schottky diode 100 with improved operating characteristics, various changes may be made to FIG. 1. For example, each component shown in FIG. 1 could be formed from any suitable material(s) and in any suitable manner. Also, each component shown in FIG. 1 could have any suitable size, shape, and dimensions. In addition, any number and type(s) of additional Group III/V integrated circuit devices could be monolithically integrated with the Schottky diode 100 using the same substrate 102 and layers 104-106, such as Group III/V field effect transistors (FETs) or high electron mobility transistors (HEMTs).

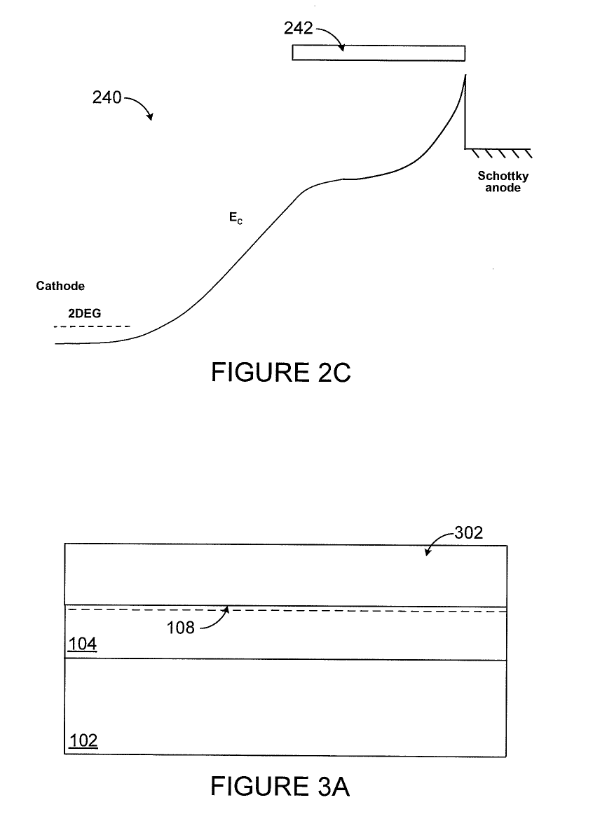

FIGS. 2A through 2C illustrate example band diagrams associated with the Group III/V-based Schottky diode 100 of FIG. 1 according to this disclosure. In FIG. 2A, a band diagram 200 represents the channel in the Schottky diode 100 from its cathode (electrical contact 110) to its anode (electrical contact 112) under zero bias. In the band diagram 200, E_{C} denotes the conduction band of the Schottky diode 100, E_{F} denotes the Fermi level of the Schottky diode 100, and φ_{B} denotes the barrier-surmounting energy needed for current flow.

In FIG. 2B, a band diagram 220 represents the channel in the Schottky diode 100 under a forward bias condition. In the band diagram 220, E_{QFN} denotes the quasi-Fermi level of electrons for the Schottky diode 100. As seen here, current flows through the Schottky diode 100 since adequate barrier-surmounting energy is provided. This causes electrons to flow to the Schottky anode (electrical contact 112), resulting in electrical current flow.

In FIG. 2C, a band diagram 240 represents the channel in the Schottky diode 100 under a reverse bias condition. In the band diagram 240, no current flows through the Schottky diode 100. Moreover, a block 242 represents the position of the “resurf electrode” portion 116 of the electrical contact 112. The portion 116 of the electrical contact 112 helps to prevent a large electric field from reaching the Schottky barrier. This allows a Schottky barrier having a lower height to be used while still withstanding a high reverse bias voltage. Once again, this allows the formation of a Group III/V-based Schottky diode with a lower barrier height that achieves lower leakage current, higher breakdown voltage, and lower turn-on voltage.

Although FIGS. 2A through 2C illustrate examples of band diagrams associated with the Group III/V-based Schottky diode 100 of FIG. 1, various changes may be made to FIGS. 2A through 2C. For example, FIGS. 2A through 2C illustrate band diagrams for a specific embodiment of the Schottky diode 100. Other embodiments of the Schottky diode 100 could have different characteristics in their band diagrams.

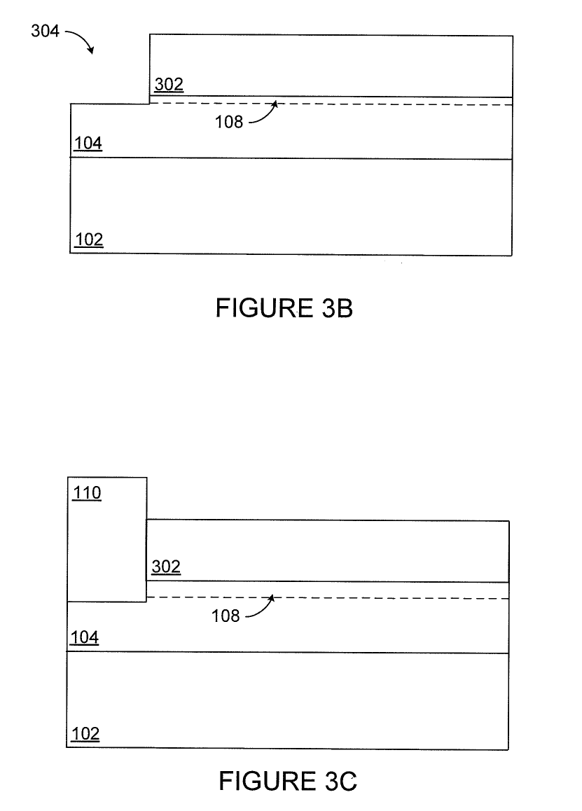

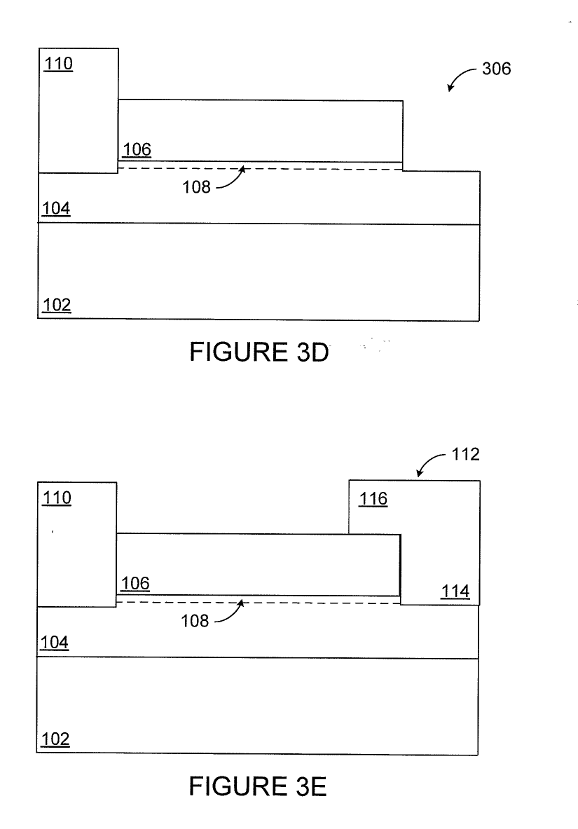

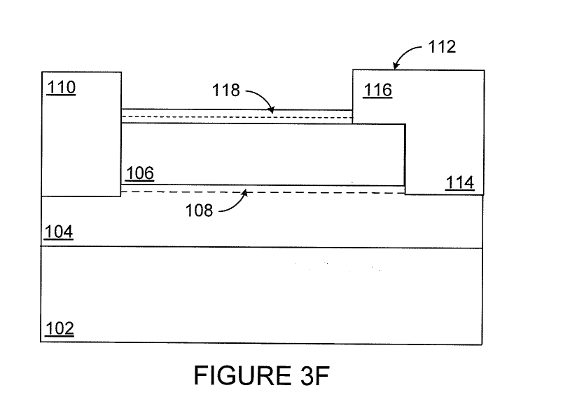

FIGS. 3A through 3F illustrate an example technique for forming the Group III/V-based Schottky diode 100 of FIG. 1 according to this disclosure. As shown in FIG. 3A, the technique begins with at least one Group III/V lower layer 104 formed over the substrate 102. The lower layer 104 can be formed in any suitable manner. For instance, the lower layer 104 could be epitaxially grown on a silicon wafer or other wafer. As a particular example, the lower layer 104 could represent gallium nitride-based nucleation, buffer, and channel layers epitaxially grown on the underlying substrate 102. At least one Group III/V layer 302 is formed over the lower layer 104. The Group III/V layer 302 could be formed from any suitable material(s) and in any suitable manner, such as by forming an aluminum gallium nitride barrier layer that is epitaxially grown on the lower layer 104. The layers 104 and 302 form an electron gas layer 108 at their interface.

As shown in FIG. 3B, a contact hole 304 is formed in the Group III/V layer 302. The contact hole 304 is where the Ohmic electrical contact 110 is going to be formed and, as noted above, may or may not be formed completely through the Group III/V layer 302. The contact hole 304 can be formed in the Group III/V layer 302 in any suitable manner, such as by masking and etching the Group III/V layer 302.

As shown in FIG. 3C, the electrical contact 110 is formed using the contact hole 304. The electrical contact 110 can be formed in any suitable manner. For example, one or more layers of conductive material can be formed over the upper layer 106 and within the contact hole 304 and then etched. The layer(s) of conductive material could include titanium, aluminum, nickel, gold, tungsten, or any other conductive material or combination of conductive materials. Once deposited, the conductive material(s) could undergo an annealing or alloying step to create an Ohmic contact. This leads to the creation of the electrical contact 110. The upper layer 106 may be protected or capped by an insulating layer (such as a sacrificial dielectric film) during this step.

As shown in FIG. 3D, a contact hole 306 is formed in the Group III/V layer 302. The contact hole 306 is where the Schottky electrical contact 112 is going to be formed. The contact hole 306 is formed completely through the Group III/V layer 302 so the electrical contact 112 can make sidewall contact with the electron gas layer 108. The contact hole 306 can be formed in the Group III/V layer 302 in any suitable manner, such as by masking and etching the Group III/V layer 302. After etching, the remaining portion of the Group III/V layer 302 represents the upper layer 106 shown in FIG. 1.

As shown in FIG. 3E, the electrical contact 112 is formed using the contact hole 306. The electrical contact 112 can be formed in any suitable manner. For example, one or more layers of conductive material can be formed over the upper layer 106 and within the contact hole 306 and then etched. The layer(s) of conductive material could include titanium, aluminum, nickel, gold, tungsten, or any other conductive material or combination of conductive materials. The electrical contact 112 is in sidewall contact with the electron gas layer 108, forming a Schottky contact. Again, the upper layer 106 may be protected or capped by an insulating layer (such as a sacrificial dielectric film) during this step. In other embodiments, the electrical contact 112 could be formed in multiple steps, such as by depositing conductive material(s) within the contact hole 306 and then depositing conductive material(s) over the upper layer 106.

As shown in FIG. 3F, at least one dielectric layer 118 is formed over the upper layer 106 between the electrical contacts 110-112. The dielectric layer(s) 118 can be formed in any suitable manner, such as by performing a low-temperature plasma oxidation of a portion of the underlying layer 106 or depositing an oxide or nitride material on the underlying layer 106. Note that each dielectric layer 118 could be formed at any suitable time, and multiple dielectric layers 118 could be formed during different steps of fabrication. For instance, one dielectric layer 118 could be formed prior to formation of the electrical contacts 110-112, and another dielectric layer 118 could be formed after formation of the electrical contacts 110-112. At least one of the dielectric layers 118 could also be formed over the electrical contacts 110-112.

After the process shown in FIGS. 3A through 3F, a Group III/V-based Schottky diode 100 has been formed, where an electron gas layer 108 formed around the interface of the layers 104-106 is electrically contacted using the contacts 110-112. Also, the contact 112 represents a Schottky contact, and the portion 116 of the contact 112 helps to prevent large electric fields from reaching the portion 114 of the contact 112. This allows the use of lower Schottky barrier heights, resulting in a lower turn-on voltage. However, the Schottky diode 100 still achieves lower leakage currents and higher breakdown voltages.

Although FIGS. 3A through 3F illustrate one example of a technique for forming the Group III/V-based Schottky diode 100 of FIG. 1, various changes may be made to FIGS. 3A through 3F. For example, the structures in the Schottky diode 100 could have any suitable sizes, shapes, dimensions, and arrangements. Also, the structures in the Schottky diode 100 could be formed in any suitable manner and in any suitable order.

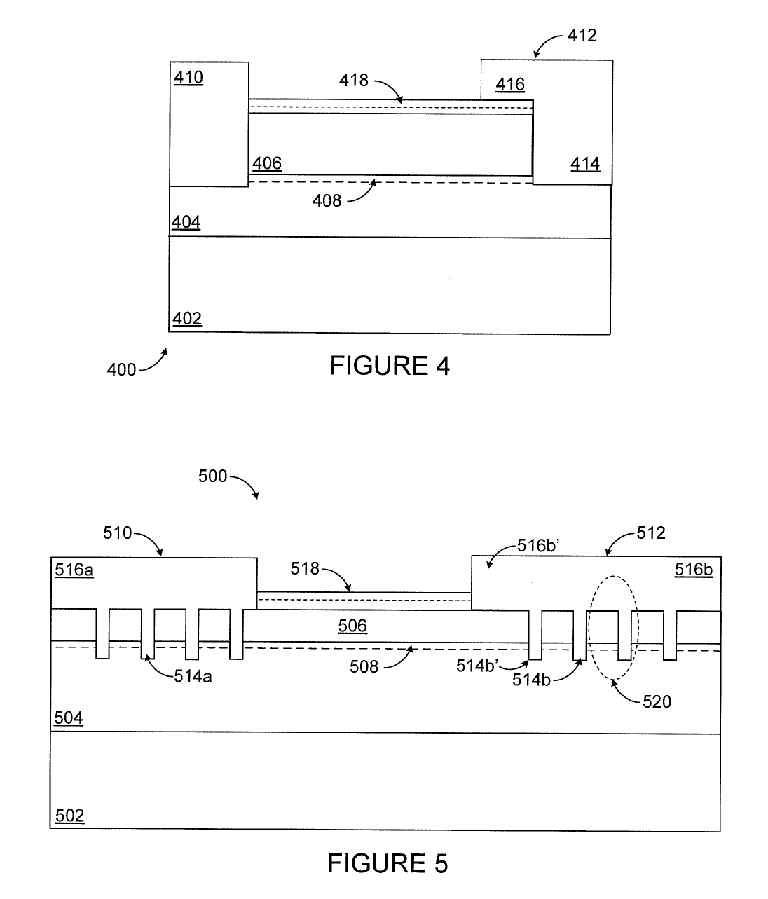

FIGS. 4 and 5 illustrate other example Group III/V-based Schottky diodes with improved operating characteristics according to this disclosure. As shown in FIG. 4, a Group III/V-based Schottky diode 400 includes a substrate 402, at least one Group III/V lower layer 404, and at least one Group III/V upper layer 406. The layers 404-406 form an electron gas layer 408 at their interface. The Schottky diode 400 also includes an electrical contact 410 (such as an Ohmic contact) and a Schottky electrical contact 412, where the contact 412 includes multiple portions 414-416. The Schottky diode 400 further includes at least one dielectric layer 418, such as a gate oxide and/or a passivation layer.

The Schottky diode 400 of FIG. 4 is similar in structure to the Schottky diode 100 of FIG. 1. In FIG. 4, the portion 416 of the electrical contact 412 is separated from the upper layer(s) 406 by the at least one dielectric layer 418. In this example, the top portion 416 of the contact 412 does not form a Schottky barrier and instead represents an insulating portion of the electrical contact 412 (insulated from the upper layer 406). However, the electrical contact 412 still wraps around a portion of the upper layer 406, providing a lower turn-on voltage with a lower Schottky height while still providing a higher breakdown voltage and a lower leakage current. The charge-reducing or charge-depleting voltage of the resurf electrode (represented by the portion 416 of the contact 412) can be selected so as not to be too negative, or higher reverse leakage current may occur.

The Schottky diode 400 of FIG. 4 could be formed in a similar manner as the Schottky diode 100 as shown in FIGS. 3A through 3F. For example, reversing the steps shown in FIGS. 3E and 3F would allow the at least one dielectric layer 418 to be formed prior to the formation of the electrical contact 412.

As shown in FIG. 5, a Group III/V-based Schottky diode 500 includes a substrate 502, at least one Group III/V lower layer 504, and at least one Group III/V upper layer 506. The layers 504-506 form an electron gas layer 508 at their interface. The Schottky diode 500 also includes an electrical contact 510 (such as an Ohmic contact) and an electrical contact 512 (a Schottky contact). The electrical contact 510 includes multiple portions 514a and 516a, and the electrical contact 512 includes multiple portions 514b and 516b. The Schottky diode 500 further includes at least one dielectric layer 518, such as a gate oxide and/or a passivation layer.

In FIG. 5, each electrical contact 510-512 includes multiple portions that extend through the upper layer(s) 506 into the lower layer(s) 504. In FIGS. 1 and 4, the electrical contacts 112 and 412 use one large sidewall contact and wrap around a single portion of the upper layers 106 and 406. In FIG. 5, each electrical contact 510-512 has multiple sidewall contacts with the electron gas layer 508, and each electrical contact 510-512 wraps around multiple portions of the upper layer(s) 506. For example, in region 520 of the Schottky diode 500, the electrical contact 512 wraps around one portion of the upper layer 506. The Schottky diode 500 can replicate the same structure repeatedly in each electrical contact 510-512. In forward bias, the multiple portions 514b of the contact 512 increase the sidewall contact area and provide lower on-resistance. In reverse bias, the resurf function is provided by a portion 516b′ of the electrical contact 512 extending beyond the last portion 514b′ of the electrical contact 512.

The Schottky diode 500 could be formed in a similar manner as that shown in FIGS. 3A through 3F. However, to form the Schottky diode 500, the etchings in FIGS. 3B and 3D could form multiple openings through the layer 302 where each contact 510-512 is to be formed. Also, the depositions of metal or other conductive material(s) shown in FIGS. 3C and 3E could fill the multiple openings through the layer 302 where each contact 510-512 is to be formed. The electrical contact 510 here could represent an Ohmic contact. Additional details regarding the formation of Ohmic contacts like this can be found in U.S. patent application Ser. No. 13/037,974, which is hereby incorporated by reference.

Since the Schottky diodes 400 and 500 still include portions overlying the upper layers 406 and 506 at the Schottky contacts 412 and 512, the Schottky contacts 412 and 512 help to reduce electron concentration near the Schottky barriers as reverse bias increases. This helps to provide a higher breakdown voltage with a lower barrier height. Once again, this allows the formation of low-leakage, high-voltage Group III/V-based Schottky diodes with a lower barrier height and a lower turn-on voltage. However, the Schottky diodes can achieve lower leakage currents and higher breakdown voltages.

Although FIGS. 4 and 5 illustrate other example Group III/V-based Schottky diodes 400 and 500 with improved operating characteristics, various changes may be made to FIGS. 4 and 5. For example, each component shown in FIGS. 4 and 5 could be formed from any suitable material(s) and in any suitable manner. Also, each component shown in FIGS. 4 and 5 could have any suitable size, shape, and dimensions. In addition, while the portions 514a-514b in FIG. 5 are shown as having substantially vertical sidewalls, the portions 514a-514b could have sidewalls that are sloped, which could provide for enhanced vertical contact with the electron gas layer 508.

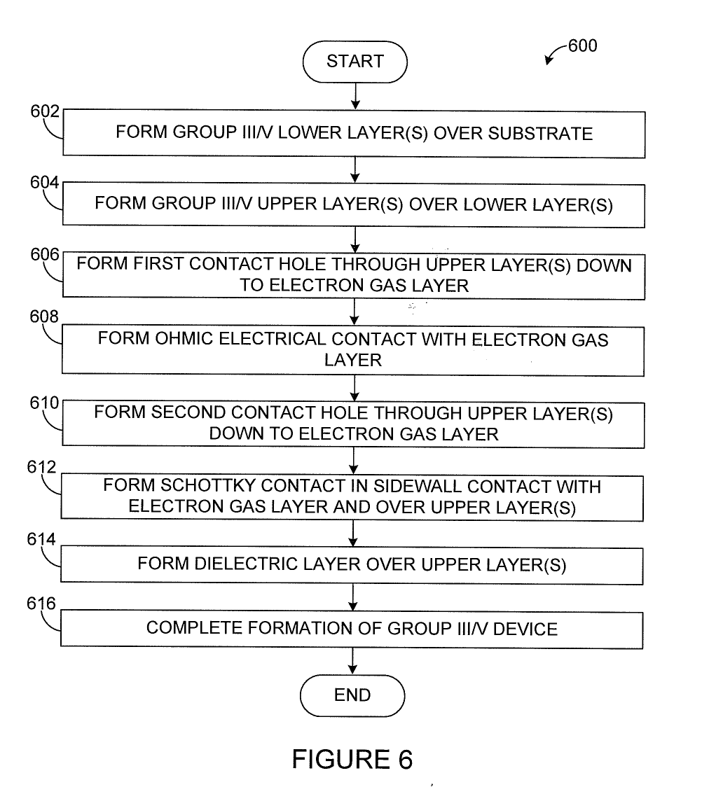

FIG. 6 illustrates an example method 600 for forming a Group III/V-based Schottky diode with improved operating characteristics according to this disclosure. For ease of explanation, the method 600 is described with respect to the Schottky diode 100 of FIG. 1. The same or similar method could be used to create any other suitable Group III/V-based Schottky diode, such as the Schottky diodes 400 and 500.

As shown in FIG. 6, at least one Group III/V lower layer is formed over a substrate at step 602, and at least one Group III/V upper layer is formed over the Group III/V lower layer(s) at step 604. This could include, for example, forming an epitaxial aluminum gallium nitride buffer layer over an aluminum nitride nucleation layer, followed by a gallium nitride channel layer. This could also include forming an aluminum gallium nitride barrier layer over the channel layer.

The upper layer is etched down to a two-dimensional electron gas layer to form a first contact hole at step 606. An electrical contact with the electron gas layer is formed at step 608. This could include, for example, etching the contact hole 304 through the aluminum gallium nitride barrier layer. The contact hole 304 could have any suitable shape, such as a square, circular, oval, slotted, or other shape. Also, any number of contact openings could be formed for the electrical contact to be created. A single large contact hole could be created for an electrical contact, or multiple smaller contact holes could be created for an electrical contact. An Ohmic electrical contact 110 could be formed by depositing one or more conductive materials, etching the conductive material(s), and performing an annealing or alloying operation. The electrical contact could be formed partially or completely through the barrier layer, or the electrical contact could be formed on top of the barrier layer.

The upper layer is etched down to the electron gas layer to form a second contact hole at step 610. A Schottky electrical contact is formed in sidewall contact with the electron gas layer and over the upper layer(s) at step 612. This could include, for example, etching the contact hole 306 through the aluminum gallium nitride barrier layer. The contact hole 306 could have any suitable shape, such as a square, circular, oval, slotted, or other shape. Also, any number of contact openings could be formed for the electrical contact to be created. A single large contact hole could be created for an electrical contact, or multiple smaller contact holes could be created for an electrical contact. A Schottky electrical contact 112 could be formed by depositing one or more conductive materials in the contact hole 306 and over the upper layer(s) 106 and etching the conductive material(s).

At least one dielectric layer is formed over the upper layer at step 614. This could include, for example, forming a gate oxide and/or a passivation layer over the upper layer 106. Formation of a Group III/V-based Schottky diode is largely completed (without back-end processing) at step 616. For example, a dielectric layer can be deposited over the electrical contacts, and openings can be formed through the dielectric layer for external contact to other components.

Although FIG. 6 illustrates one example of a method 600 for forming a Group III/V-based Schottky diode with improved operating characteristics, various changes may be made to FIG. 6. For example, while shown as a series of steps, various steps in FIG. 6 could overlap, occur in parallel, occur in a different order, or occur multiple times. As a particular example, a dielectric layer could be formed over the upper layer at any suitable time, such as prior to formation of one or more of the electrical contacts.

It may be advantageous to set forth definitions of certain words and phrases that have been used within this patent document. The term “couple” and its derivatives refer to any direct or indirect communication between two or more components, whether or not those components are in physical contact with one another. The terms “include” and “comprise,” as well as derivatives thereof, mean inclusion without limitation. The term “or” is inclusive, meaning and/or. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like.

While this disclosure has described certain embodiments and generally associated methods, alterations and permutations of these embodiments and methods will be apparent to those skilled in the art. Accordingly, the above description of example embodiments does not define or constrain this invention. Other changes, substitutions, and alterations are also possible without departing from the spirit and scope of this invention as defined by the following claims.

What is claimed is:

1. A semiconductor device comprising:
a first Group III/V layer and a second Group III/V layer over the first Group III/V layer, the first and second Group III/V layers configured to form an electron gas layer; and
a Schottky electrical contact comprising first and second portions, the first portion in sidewall contact with the electron gas layer, the second portion over the second Group III/V layer and in electrical connection with the first portion of the Schottky electrical contact.

2. The semiconductor device of claim 1, wherein:
the first portion of the Schottky electrical contact and the first or second Group III/V layer form a Schottky barrier; and
the second portion of the Schottky electrical contact is configured to reduce an electron concentration near the Schottky barrier under reverse bias.

3. The semiconductor device of claim 1, wherein the first and second portions of the Schottky electrical contact wrap around a portion of the second Group III/V layer.

4. The semiconductor device of claim 1, further comprising:
a dielectric layer over the second Group III/V layer.

5. The semiconductor device of claim 4, wherein part of the dielectric layer is between the second portion of the Schottky electrical contact and the second Group III/V layer.

6. The semiconductor device of claim 1, wherein the Schottky electrical contact comprises multiple first portions in sidewall contact with the electron gas layer.

7. The semiconductor device of claim 1, further comprising:
a second electrical contact in sidewall contact with a side of at least the second Group III/V layer.

8. The semiconductor device of claim 7, wherein the second electrical contact comprises an Ohmic contact.

9. The semiconductor device of claim 1, wherein:
the first Group III/V layer comprises a Group III/V nucleation layer, a Group III/V buffer layer, and a Group III/V channel layer; and
the second Group III/V layer comprises a Group III/V barrier layer.

10. A system comprising:
multiple semiconductor devices including a Group III/V Schottky diode, the Schottky diode comprising:
a first Group III/V layer and a second Group III/V layer over the first Group III/V layer, the first and second Group III/V layers configured to form an electron gas layer; and
a Schottky electrical contact comprising first and second portions, the first portion in sidewall contact with the electron gas layer, the second portion over the second Group III/V layer and in electrical connection with the first portion of the Schottky electrical contact.

11. The system of claim 10, wherein:
the first portion of the Schottky electrical contact and the first or second Group III/V layer form a Schottky barrier; and
the second portion of the Schottky electrical contact is configured to reduce an electron concentration near the Schottky barrier under reverse bias.

12. The system of claim 10, wherein the Schottky diode further comprises:
a dielectric layer over the second Group III/V layer.

13. The system of claim 12, wherein part of the dielectric layer is between the second portion of the Schottky electrical contact and the second Group III/V layer.

14. The system of claim 10, wherein the Schottky electrical contact comprises multiple first portions in sidewall contact with the electron gas layer.

15. The system of claim 10, wherein the Schottky diode further comprises:
a second electrical contact in sidewall contact with a side of at least the second Group III/V layer.

16. The system of claim 15, wherein the second electrical contact comprises an Ohmic contact.

17. The system of claim 10, wherein the semiconductor devices comprise the Schottky diode and one or more monolithically integrated transistors.

18. A method comprising:
forming a first Group III/V layer and a second Group III/V layer over the first Group III/V layer, the first and second Group III/V layers configured to form an electron gas layer; and
forming a Schottky electrical contact comprising (i) a first portion in sidewall contact with the electron gas layer and (ii) a top second portion over the second Group III/V layer and in electrical connection with the first portion of the Schottky electrical contact.

19. The method of claim 18, further comprising:
forming a dielectric layer over the second Group III/V layer;
wherein part of the dielectric layer is between the second portion of the Schottky electrical contact and the second Group III/V layer.

20. The method of claim 18, wherein forming the Schottky electrical contact comprises forming multiple first portions in sidewall contact with the electron gas layer.
